(19) United States
(12) Patent Application Publication
(10) Pub. No.: US 2003/0124465 A1
(43) Pub. Date: Jul. 3, 2003

(54) Method for fabricating semiconductor device capable of covering facet on plug

(76) Inventors: Sung-Kwon Lee, Ichon-shi (KR); Min-Suk Lee, Ichon-shi (KR); Sang-Ik Kim, Ichon-shi (KR); Chang-Youn Hwang, Ichon-shi (KR); Weon-Joon Suh, Ichon-shi (KR)

Correspondence Address: BIRCH STEWART KOLASCH & BIRCH, PO BOX 747, FALLS CHURCH, VA, 22040-0747, US

(21) Appl. No.: 10/293,497

(22) Filed: Nov. 14, 2002

(30) Foreign Application Priority Data
Dec. 27, 2001 (KR) 2001-86313

(51) Int. Cl. G03F 7/16; G03F 7/36; H01L 21/44

(52) U.S. Cl. 430/314; 438/675; 430/317

(57) ABSTRACT

The present invention relates to a method for fabricating a semiconductor device capable of improving an overlap margin that occurs when forming a conductive pattern, such as a bit line or a bit line contact. In order to achieve this effect, the method for fabricating a semiconductor device includes the steps of: forming a plug passing through an insulation layer to be contacted with a substrate board; forming a planarization insulation layer on an entire surface including the plug so as to cover defects appeared at a surface of the plug; forming a protective insulation layer on the planarization insulation layer for preventing losses of the planarization insulation layer resulted from a subsequent cleaning process; performing a process with an etchant; and forming a conductive layer contacted to the plug by passing through the protective insulation layer and the planarization insulation layer.

### FIELD OF THE INVENTION

The present invention relates to a method for fabricating a semiconductor device; and, more particularly, to a method for covering a facet on plug.

### DESCRIPTION OF RELATED ARTS

There has been actively studied on a method for forming a plug by performing a selective epitaxial growth (hereinafter referred as to SEG). The plug is formed after performing an etch process, which is one of processes for fabricating a semiconductor device. The SEG for forming the plug has an advantage in reducing a contact resistance 1.5 times greater than using a typical deposition technique. On the other hand, after performing the SEG, a high density plasma (hereinafter referred as to HDP) oxide layer is deposited as an inter-layer insulation layer and a chemical mechanical polishing (hereinafter referred as to CMP) is performed to isolate the plug. The HDP oxide layer is an oxide layer deposited in an apparatus providing high density plasma. After the CMP, the following two cases are proceeded. For one case, an undoped silicate glass (hereinafter referred as to USG) is deposited, and a bit line is formed after forming a bit line contact hole by an etching the USG. For another case, a HDP oxide layer is formed, an etch back process using a plasma is performed, and a bit line is formed after forming a bit line contact hole by etching the HDP oxide layer.

However, there result in problems when proceeding the above mentioned processes. A micro-dishing phenomenon occurs by applying the CMP process to the HDP oxide layer, which results in a short between the bit lines. When a SEG facet is excessively developed, defect, such as a micro void or an opening, is generated in a HDP oxide layer at the step of depositing the HPD oxide layer. Especially, these defects progress substantially further through the step of applying an etch back to the HDP oxide layer. During subsequent etch processes for forming a bit line contact hole or a bit line with tungsten W, more defects are generated due to a micro-step difference resulted from the above defect and the void. Thus, a shortage of a depth of focus (DOF) margin during a photo-etch process is induced, and a device failure is generated.

Meanwhile, in case of a next generation semiconductor device, an overlap margin between the bit line and the bit line contact hole decreases remarkably because of diminished restrictions in layout and process aspects.

In a method for fabricating a semiconductor device having a line width less than 0.1 μm, spaces of the contact hole and so forth decrease while an aspect ratio increases. Thus, it is impossible to carry out a complete filling, with respect to a gap-fill property of an insulating, thereby resulting in problems of voids. In order to solve these problems, a technology to form a flowable insulation layer has been actively studied. An advanced planarization layer (APL) thin layer is an insulation layer having a flow property.

Among various techniques related to the APL thin layer, self planarization chemical vapor deposition (hereinafter referred as to CVD) forms a reaction intermediate having a substantially high degree of fluidity, and thus, a complete filling planarization can be attained when forming a layer. Hence, a planarized inter-layer insulation layer can be formed through a simple single process, which, in turn, allows process costs to be reduced effectively compared to use of a typical complex process. In more detail, the self planarization CVD uses a low pressure chemical vapor deposition (hereinafter referred as to LPCVD) to ultimately form the planarized inter-layer insulation layer with use of H₂O₂ and SiH₄ as a reactant source and has an excellent gap-fill property due to its flow property.

In summary, the flowable inter-layer insulation layer possesses an excellent gap-fill property, high stability of a layer, no occurrence of cracks and lifting, low thermal budget because of the deposition performed at a temperature less than 650° C., tolerance to a temperature greater than 1000° C. and tolerance to strong chemicals and a property of planarization.

In spite of all these advantages, the flowable interlayer insulation layer has a high rate of an etching speed when performing a pre-cleaning process in accordance with a wet cleaning that employs an etchant such as HF or a buffered oxide etchant (hereinafter referred as to BOE). The dilution of the etchant to the water is from about 100:1 to about 500:1. Therefore, top critical dimension widening phenomenon is observed and this phenomenon results in a decrease of the overlap margin between a bit line and a bit line contact during a process for forming the bit line after depositing a conductive material.

### SUMMARY OF THE INVENTION

It is, therefore, an object of the present invention to provide a method for fabricating a semiconductor device capable of improving an overlap margin during a formation of a conductive layer, such as a bit line or a bit line contact.

In accordance with an aspect of the present invention, there is provided a method for fabricating a semiconductor device, comprising the steps of: forming a plug passing through an insulation layer to be contacted with a substrate board; forming a planarization insulation layer on an entire surface including the plug so as to cover defects appeared at a surface of the plug; forming a protective insulation layer on the planarization insulation layer for preventing losses of the planarization insulation layer resulted from a subsequent cleaning process; performing a process with an etchant; and forming a conductive layer contacted to the plug by passing through the protective insulation layer and the planarization insulation layer.

In accordance with the present invention, during a planarization process for forming a plug, surface defects are covered with a flowable insulation layer or an undoped silicate glass (USG) layer that formed with SiH₄, that is a facet on the top portion of the plug, which results in subsequent defects occurring at a later processes for forming a bit line and a bit line contact, is covered with a flowable insulation layer or the USG layer. A tetra ethyl ortho silicate (TEOS) layer or a high density plasma (HDP) oxide layer is stacked on the flowable insulation layer or the USG layer.

### BRIEF DESCRIPTION OF THE DRAWING(S)

The above and other objects and features of the present invention will become apparent from the following description of the preferred embodiments given in conjunction with the accompanying drawings, in which:

FIGS. 1 to 5 are cross-sectional views illustrating a fabricating process of a semiconductor device in accordance with a preferred embodiment of the present invention.

### DETAILED DESCRIPTION OF THE INVENTION

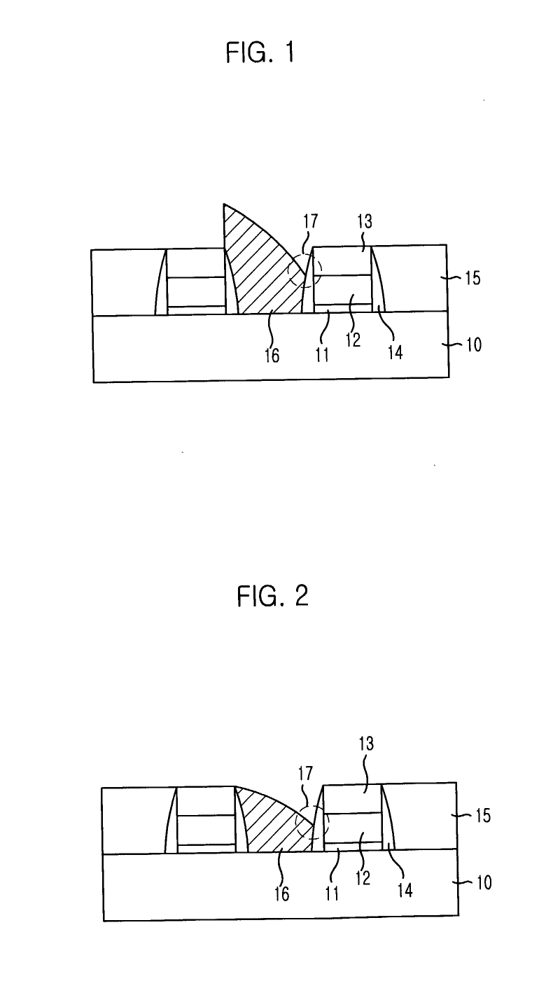

First of all, with reference to FIG. 1, a number of conductive patterns are formed on a substrate 10. The conductive patterns are bit lines or gate electrodes, and the gate electrodes will be taken as an exemplary conductive pattern for this preferred embodiment.

In more detail, oxide layer based gate insulation layer 11, a conductive layer 12 for gate electrode and a nitride layer for a hard mask 13 are sequentially deposited and a photo-etch process is performed with a mask to form a gate electrode. In this preferred embodiment, the conductive layer 12 for the gate electrode is formed with a single or mixtures of polysilicon layer, tungsten layer and tungsten silicide layer.

Then, a spacer 14 is formed to protect lateral sides of the gate insulation layer 11 and the conductive layer 12. At this time, the spacer 14 is formed by depositing and etching a silicon nitride layer or silicon oxide nitride layer. In this preferred embodiment, the silicon nitride layer or the silicon oxide nitride layer is deposited to a thickness ranging from about 100 Å to about 500 Å.

An inter-layer insulation layer 15 is deposited as much as possible to fill spaces between neighboring patterns, i.e., the spacers 14. After depositing the inter-layer insulation layer 15, a surface of the substrate 10 between the gate electrodes, e.g., a source or a drain, a impurity diffusion area, is opened through an etch process. Then, a plug 16 contacted to the surface of the substrate 10 is formed by a selective epitaxial growth (hereinafter referred as to SEG) or a deposition of a polysilicon layer. At this time, a facet 17 is generated as shown in FIG. 1.

Next, an insulation layer(not shown) is formed to isolate the neighboring plug 16 with use of a high density plasma (hereinafter referred as to HDP) oxide layer.

Referring to FIG. 2, a planarization process such as chemical mechanical polishing (hereinafter referred as to CMP) process or dry etch back process is applied to the insulation layer 18 so as to isolate each plug 16 formed. Despite of this planarization process, the facet 17 is still remained and becomes a burden when forming a conductive pattern, such as a bit line or a bit line contact.

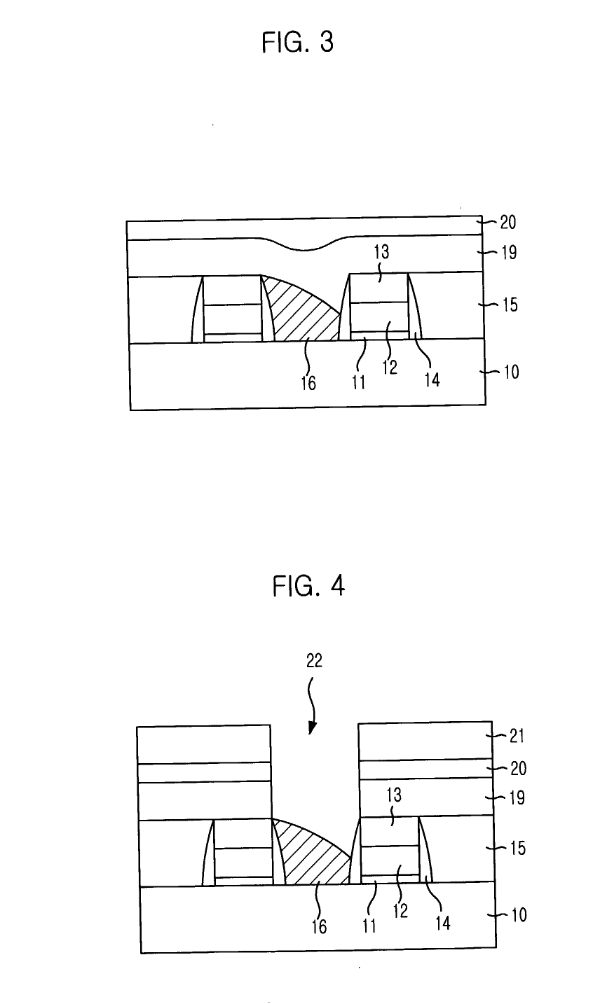

Accordingly, as shown in FIG. 3, a planarization insulation layer 19 for covering a surface defect, i.e., the facet 17, is formed on an entire surface of the substrate 10 including the plug 16. In this preferred embodiment, the planarization insulation layer 19 is formed with a flowable insulation layer or USG layer using siH₄.

On the planarization layer 19, a protective insulation layer 20 is formed with a tetra ethyl ortho silicate (hereinafter referred as to TEOS) layer or a HDP oxide layer for preventing losses of the planarization insulation layer 19 in a subsequent cleaning process. It is possible for the protective insulation layer 20 to protect the planarization insulation layer 19 during the actual operation of the cleaning process. In case of using the HDP oxide layer, a thickness of the protective insulation layer 20 is in a range from about 500 Å to about 3000 Å. On the other hand, in case of using the TEOS layer, a thickness of the protective insulation layer 20 is in a range from about 500 Å to about 3000 Å, whereas the thickness is in a range from about 500 Å to about 3000 Å in case of using SiH₄.

After forming the protective insulation layer 20, a process with an etchant, such as an etching or a cleaning, is carried out. In the preferred embodiment, an etch process is described as follows.

Referring to FIG. 4, a photoresist pattern 21 for forming a contact hole is formed on the protective insulation layer 20. The photoresist pattern 21 functions as an etch mask when the planarization insulation layer 19 and the protective insulation layer 20 are sequentially etched with HF or buffered oxide etchant(herein after referred as BOE). Because of this etching process, an opening portion 22 that exposes a surface of the plug 16 is formed. Concurrently, since the planarization insulation layer 19 and the protective layer 20 complement defects occurred at bottom portions of the semiconductor device while simultaneously achieving the layer planarization, it is possible to attain a process margin at the steps of coating and exposing a photoresist.

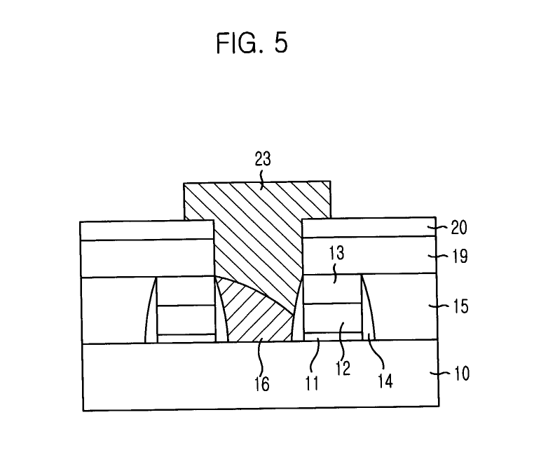

With reference to FIG. 5, the opening portion 22 is filled with a conductive layer 23 contacted to the plug 16. The conductive layer 23 is formed with a single layer or multi-layers of W, WSi or metal silicide in till reaching a thickness in a range from about 500 Å to about 3000 Å. Also, a barrier layer(not shown) can be formed additionally on an interface between the conductive layer 23 and the plug 16 with a thickness in a range from about 50 Å to about 1000 Å by using Ti, TiN, TiW, TaW, TaN or WN and so on. It is possible to prevent short between conductive patterns such as bit line, due to the planarization of the insulation layer in accordance with the preferred embodiment of the present invention.

As described above, the preferred embodiment clearly demonstrates that it is possible to overcome defects such as the facet on the plug surface and problems resulted from the cleaning process through the formations of the planarization insulation layer, e.g., flowable insulation layer and the protective insulation layer, e.g., TEOS layer on the top surface of the plug. As a result of these advantages, a process margin can also be improved during a subsequent process and degradation of semiconductor device properties can be ultimately prevented.

While the present invention has been described with respect to certain preferred embodiments, it will be apparent to those skilled in the art that various changes and modifications may be made without departing from the scope of the invention as defined in the following claims.

What is claimed is:

1. A method for fabricating a semiconductor device, comprising the steps of:
forming a plug passing through an insulation layer to be contacted with a substrate;
forming a planarization insulation layer on an entire surface including the plug so as to cover defects appeared at a surface of the plug;
forming a protective insulation layer on the planarization insulation layer for preventing losses of the planarization insulation layer resulted from a subsequent cleaning process;
performing a process with an etchant; and
forming a conductive layer contacted to the plug by passing through the protective insulation layer and the planarization insulation layer.

2. The method as recited in claim 1, wherein the etchant is dilute HF or BOE.

3. The method as recited in claim 2, wherein the dilution of the etchant to the water is from about 100:1 to about 500:1.

4. The method as recited in claim 1, wherein the planarization insulation layer includes a flowable insulation layer or a undoped silicate glass (USG) layer that uses SiH₄.

5. The method as recited in claim 4, wherein the flowable insulation layer is An advanced planarization layer.

6. The method as recited in claim 4, wherein the flowable insulation layer is formed with a thickness in a range from about 500 Å to about 3000 Å.

7. The method as recited in claim 4, wherein the USG layer that uses SiH₄ is formed with a thickness in a range from about 500 Å to about 3000 Å.

8. The method as recited in claim 1, wherein the protective insulation layer includes a high density plasma (HDP) oxide layer or a tetra ethyl ortho silicate (TEOS) layer.

9. The method as recited in claim 8, wherein the HDP oxide layer has a thickness in a range from about 500 Å to about 3000 Å.

10. The method as recited in claim 8, wherein the TEOS layer is formed with a thickness in a range from about 500 A to about 3000 Å.

11. The method as recited in claim 1, wherein the plug is formed through the use of a selective epitaxial growth (SEG).
